(19) United States
(12) Patent Application Publication
(10) Pub. No.: US 2010/0022093 A1
(43) Pub. Date: Jan. 28, 2010

(54) VACUUM PROCESSING APPARATUS, METHOD OF OPERATING SAME AND STORAGE MEDIUM

(75) Inventor: Hirofumi YAMAGUCHI, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/568,709

(22) Filed: Sep. 29, 2009

Related U.S. Application Data
(63) Continuation of application No. PCT/JP2008/055680, filed on Mar. 26, 2008.

(30) Foreign Application Priority Data
Mar. 29, 2007 (JP) 2007-088021

(51) Int. Cl. H01L 21/465

(52) U.S. Cl. 438/706; 118/719; 156/345.31; 438/758; 257/E21.485

(57) ABSTRACT

In a vacuum processing apparatus including a processing chamber having a transfer port, and a transfer chamber connected via a gate chamber to the transfer port, diffusion of a gas remaining in the processing chamber into the transfer chamber is suppressed. In order to suppress diffusion of gas from the processing chamber into the transfer chamber, the gate chamber is provided with a non-reactive gas supply unit and an exhaust port adapted to produce a stream of a non-reactive gas at a region facing the transfer port. This suppresses diffusion of gas from the processing chamber into the transfer chamber through the transfer port.

This application is a Continuation Application of PCT International Application No. PCT/JP2008/055680 filed on Mar. 26, 2008, which designated the United States.

### FIELD OF THE INVENTION

The present invention relates to a vacuum processing apparatus, a method of operating same and a storage medium, wherein the apparatus includes a processing chamber which performs vacuum processing on a substrate and a transfer chamber which is connected via a gate chamber to the processing chamber and has a transfer unit for delivering the substrate.

### BACKGROUND OF THE INVENTION

In a manufacture of semiconductor devices, a semiconductor wafer serving as a substrate to be processed is often subjected to a gas-involving process, such as dry etching, CVD (Chemical Vapor Deposition) or the like using a processing gas. As for a processing apparatus for performing such gas-involving process, there is known a multi-chamber type which includes a transfer chamber having a wafer transfer mechanism and a plurality of processing modules each for performing a predetermined process in view of processing a plurality of wafers at a high throughput, each processing module including a processing chamber connected with the transfer chamber via a gate chamber.

Each processing chamber has a wafer transfer port, and each transfer port can be opened and closed by a gate valve provided at the gate chamber. The transfer chamber is provided with a non-reactive gas supply port and a non-reactive gas exhaust port, and the processing chamber is provided with a processing gas supply port and a processing gas exhaust port. The insides of the transfer chamber and the processing chamber are maintained in a vacuum state. Further, when predetermined gas treatment is performed in the processing chamber, the transfer chamber and the processing chamber do not communicate with each other by closing the gate valve. When a wafer is transferred between the transfer chamber and the processing chamber, the transfer chamber and the processing chamber communicate with each other by opening the gate valve.

However, in this vacuum processing apparatus, a processing gas, a by-product gas and/or the like remains in the processing chamber after completion of the treatment in the processing chamber. If these gases are diffused into the transfer chamber via the gate chamber by opening the gate valve, this may cause contamination. Further, the wafer may be contaminated by particles generated from the gas attached to the transfer chamber, or the components in the transfer chamber may be corroded. Therefore, the transfer chamber needs to be cleaned regularly and frequently.

Conventionally, in order to avoid the above-described drawbacks, the inside of the transfer chamber is maintained at, e.g., several tens to several hundreds of Pa. Further, when the wafer is transferred between the transfer chamber and the processing chamber, the diffusion of the gas from the processing chamber into the transfer chamber is prevented by opening the gate valve after a predetermined pressure difference is produced between the transfer chamber and the processing chamber by lowering a pressure P0 in the processing chamber below a pressure P1 in the transfer chamber (P0<P1).

Since, however, the transfer chamber is also exhausted, the non-reactive gas flows toward the gas exhaust port thereof despite the pressure difference and the non-reactive gas may not flow from the transfer chamber to the transfer port of the processing chamber, so that the diffusion of the gas from the processing chamber may not be sufficiently suppressed. To that end, it is considered to further increase the pressure in the processing chamber. However, this increases the consumption amount of the non-reactive gas, which leads to a cost increase. Further, when the pressure in the transfer chamber is set in a transition region between a viscous and a molecular flow regime of the non-reactive gas or in the molecular flow regime, it is difficult for the non-reactive gas to flow according to the pressure difference. In that case, the gas may be more easily diffused from the processing chamber.

Moreover, Patent Document 1 describes a vacuum processing apparatus wherein a gas exhaust port is provided in a housing of a gate valve. However, the object of the invention of Patent Document 1 is different from that of the present invention.

Patent Document 1: Japanese Patent Laid-open Application No. 2001-291785 (Paragraph [0027] and FIG. 3)

### SUMMARY OF THE INVENTION

The present invention was conceived to address the aforementioned drawbacks. It is therefore the object of the present invention to provide a vacuum processing apparatus, an operating method thereof, and a storage medium, wherein the apparatus includes a processing chamber for performing a process on a substrate by a processing gas and a transfer chamber which is connected with a transfer port of the processing chamber via a gate chamber and has a transfer unit for transferring the substrate with respect to the processing chamber, the vacuum processing apparatus being capable of suppressing diffusion of a gas remaining in the processing chamber into the transfer chamber while the transfer port is opened.

In accordance with a first aspect of the present invention, there is provided a vacuum processing apparatus including a processing chamber having a substrate transfer port and performing a processing on a substrate by using a processing gas in a vacuum atmosphere; a transfer chamber in a vacuum atmosphere connected via a gate chamber to the transfer port of the processing chamber and equipped with a transfer unit for transferring the substrate with respect to the processing chamber; a gate valve provided in the gate chamber for closing the transfer port when the substrate is processed in the processing chamber and opening the transfer port when the substrate is transferred with respect to the processing chamber; and a gate chamber non-reactive gas supply unit and a gate chamber exhaust port provided at the gate chamber, which produce a stream of a non-reactive gas at a region facing the transfer port to suppress diffusion of a gas remaining in the processing chamber into the transfer chamber at least while the transfer port is opened.

In the first aspect of the present invention, when the gate valve in the gate chamber is closed, the supply of the non-reactive gas from the gate chamber non-reactive gas supply unit is stopped.

In the first aspect of the present invention, the transfer chamber is provided with a transfer chamber non-reactive gas supply unit and a transfer chamber exhaust port to produce a stream of non-reactive gas within the transfer chamber.

In the first aspect of the present invention, when the gate valve in the gate chamber is closed, the gate chamber exhaust port of the gate chamber is closed.

In the first aspect of the present invention, the gate valve is configured to open and close the gate chamber exhaust port in unison with the opening and closing of the transfer port.

In the first aspect of the present invention, the gate valve has an opening at a position overlapping with the gate chamber exhaust port such that the gate chamber exhaust port is opened while the transfer port is opened.

In the first aspect of the present invention, the vacuum processing apparatus further includes one or more processing chambers, each being connected to the transfer chamber via a gate chamber.

In accordance with a second aspect of the present invention, there is provides a vacuum processing apparatus including a plurality of processing chambers, each having a substrate transfer port and performing a processing on a substrate by using a processing gas in a vacuum atmosphere; a transfer chamber in a vacuum atmosphere connected via a gate chamber to the transfer port of the processing chambers and equipped with a transfer unit for transferring the substrate with respect to the processing chambers via the transfer port; a gate valve provided in the gate chamber for closing the transfer port when the substrate is processed in the processing chamber and opening the transfer port when the substrate is transferred with respect to the processing chamber; one or more first transfer chamber non-reactive gas supply units provided in the transfer chamber and a gate chamber exhaust port provided at the gate chamber, which produce a stream of a non-reactive gas at a region facing the transfer port to suppress diffusion of a gas remaining in said each of the processing chambers into the transfer chamber; a second transfer chamber non-reactive gas supply unit provided in the transfer chamber to produce a stream of a non-reactive gas in the transfer chamber; and a transfer chamber exhaust port provided in the transfer chamber to exhaust the transfer chamber and adapted to be closed when the stream of the non-reactive gas is produced in the gate chamber, wherein when the gate valve is closed, the gate chamber exhaust port of the gate chamber is closed.

In the second aspect of the present invention, the first transfer chamber non-reactive gas supply units are provided for the transfer ports of the processing chambers in a one-to-one relationship.

In the second aspect of the present invention, the number of the first transfer chamber non-reactive gas supply unit is one and a single unit is commonly used as the first and the second transfer chamber non-reactive gas supply unit.

In accordance with a third aspect of the present invention, there is provides an operating method of a vacuum processing apparatus which includes a processing chamber having a substrate transfer port, a transfer chamber connected via a gate chamber to the transfer port and equipped with a transfer unit for transferring a substrate with respect to the processing chamber via the transfer port in a vacuum atmosphere, the operating method including processing the substrate in the processing chamber with the use of a processing gas in a vacuum atmosphere while closing the transfer port by a gate valve provided in the gate chamber; unloading the substrate from the processing chamber by the transfer unit while opening the transfer port by the gate valve; and producing, at least while the transfer port is opened, a stream of a non-reactive gas at a region facing the transfer port by a gate chamber non-reactive gas supply unit and a gate chamber exhaust port provided at the gate chamber to suppress diffusion of a gas remaining in the processing chamber into the transfer chamber.

In the third aspect of the present invention, when the gate valve of the gate chamber is closed, supply of the non-reactive gas from the gate chamber non-reactive gas supply unit is stopped.

In the third aspect of the present invention, the operating method further includes producing a stream of a non-reactive gas in the transfer chamber by a transfer chamber non-reactive gas supply unit and a transfer chamber exhaust port provided at the transfer chamber.

In the third aspect of the present invention, when the gate valve in the gate chamber is closed, the gate chamber exhaust port of the gate chamber is closed.

In accordance with a fourth aspect of the present invention, there is provided an operating method of a vacuum processing apparatus which includes a processing chamber having a substrate transfer port, a transfer chamber connected via a gate chamber to the transfer port and equipped with a transfer unit for transferring a substrate with respect to the processing chamber in a vacuum atmosphere, the operating method including processing the substrate in the processing chamber with the use of a processing gas in a vacuum atmosphere while closing the transfer port by a gate valve provided in the gate chamber; unloading the substrate from the processing chamber by the transfer unit while opening the transfer port by the gate valve; and closing the gate chamber exhaust port provided at the gate chamber when the gate valve is closed.

Further, the operating method of the fourth aspect of the invention further includes, at least while the transfer port is opened, producing a stream of a non-reactive gas at a region facing the transfer port by a first transfer chamber non-reactive gas supply unit provided in the transfer chamber and a gate chamber exhaust port provided at the gate chamber, to suppress diffusion of a gas remaining in the processing chamber into the transfer chamber; producing a stream of a non-reactive gas in the transfer chamber by a second transfer chamber non-reactive gas supply unit provided in the transfer chamber; and closing an exhaust port provided at the transfer chamber to exhaust the transfer chamber when the stream of the non-reactive gas is produced in the gate chamber.

In accordance with a fifth aspect of the present invention, there is provided a storage medium storing therein a computer program for executing an operating method of a vacuum processing apparatus by computer which includes a processing chamber having a substrate transfer port, a transfer chamber connected via a gate chamber to the transfer port and equipped with a transfer unit for transferring a substrate with respect to the processing chamber via the transfer port in a vacuum atmosphere, wherein the operating method includes processing the substrate in the processing chamber with the use of a processing gas in a vacuum atmosphere while closing the transfer port by a gate valve provided in the gate chamber; unloading the substrate from the processing chamber by the transfer unit while opening the transfer port by the gate valve; and producing, at least while the transfer port is opened, a stream of a non-reactive gas at a region facing the transfer port by a gate chamber non-reactive gas supply unit and a gate chamber exhaust port provided at the gate chamber to suppress diffusion of a gas remaining in the processing chamber into the transfer chamber.

In accordance with a sixth aspect of the present invention, there is provides a storage medium storing therein a computer program for executing an operating method of a vacuum processing apparatus by computer which includes a processing chamber having a substrate transfer port, a transfer chamber connected via a gate chamber to the transfer port and equipped with a transfer unit for transferring a substrate with respect to the processing chamber in a vacuum atmosphere, wherein the operating method includes processing the substrate in the processing chamber with the use of a processing gas in a vacuum atmosphere while closing the transfer port by a gate valve provided in the gate chamber; unloading the substrate from the processing chamber by the transfer unit while opening the transfer port by the gate valve; and closing a gate chamber exhaust port provided at the gate chamber when the gate valve is closed.

The operating method of the sixth aspect of the invention further includes, at least while the transfer port is opened, producing a stream of a non-reactive gas at a region facing the transfer port by a first transfer chamber non-reactive gas supply unit provided in the transfer chamber and the gate chamber exhaust port, to suppress diffusion of a gas remaining in the processing chamber into the transfer chamber; producing a stream of a non-reactive gas in the transfer chamber by a second transfer chamber non-reactive gas supply unit provided in the transfer chamber; and closing an exhaust port provided at the transfer chamber to exhaust the transfer chamber when the stream of the non-reactive gas is produced in the gate chamber.

In accordance with the vacuum processing apparatus of the present invention, the transfer chamber having the transfer unit for transferring the substrate is connected via the gate chamber with the transfer port of the processing chamber for performing a process on the substrate by the processing gas. The gate chamber is provided with the gate valve for opening and closing the transfer port. Further, the gate chamber is provided with the gate chamber non-reactive gas supply unit and the gate chamber exhaust port adapted to produce a stream of the non-reactive gas at its position facing the transfer port. Accordingly, it is possible to suppress the contamination of the inside of the transfer chamber by the diffusion of the gas remaining in the processing chamber into the transfer chamber through the transfer port.

In accordance with another vacuum processing apparatus of the present invention, the transfer chamber having the transfer unit for transferring the substrate is connected via the gate chamber with the transfer port of each of a plurality of processing chambers for performing a process on the substrate by the processing gas. The gate chambers are provided with the gate valve for opening and closing the transfer port. Further, the transfer chamber is provided with the first transfer chamber non-reactive gas supply unit and the gate chamber is provided with the gate chamber exhaust port, to thereby produce a stream of the non-reactive gas at a region facing the transfer port. Moreover, the transfer chamber is provided with the transfer chamber exhaust port for exhausting the transfer chamber, wherein the transfer chamber exhaust port is closed when the stream of the non-reactive gas is produced in the gate chamber. Accordingly, it is possible to suppress the contamination of the transfer chamber by the diffusion of the gas remaining in the processing chamber through the transfer port.

### BRIEF DESCRIPTION OF THE DRAWINGS

FIG. 1 is a top view of a semiconductor manufacturing apparatus including a gate valve of the present invention.

FIG. 2 illustrates a vertical side view of the gate valve, a second transfer chamber and a CVD module provided at the semiconductor manufacturing apparatus.

FIGS. 3A and 3B show a structure of a gas nozzle provided at the gate valve.

FIG. 4 provides a perspective view of the gate valve, the gas nozzle, a gas exhaust port, and a substrate transfer port of the CVD module.

FIGS. 5A to 5C are views showing various states of gas supply and exhaust produced by the gate valve during a wafer transfer process.

FIGS. 6A and 6B are showing various states of a gas supply and exhaust produced by the gate valve during the wafer transfer process.

FIGS. 7A and 7B present a vertical side view showing a configuration of another gate valve.

FIG. 8 is a vertical side view illustrating a configuration of still another gate valve.

FIGS. 9A to 9C are views showing various states of a gas supply and exhaust produced by the still another gate valve during a wafer transfer process.

FIG. 10 is a vertical side view of still another gate valve and a transfer chamber connected thereto.

FIGS. 11A to 11C are views of various states of depicting a gas supply and exhaust produced by the gate valve and the transfer chamber shown in FIG. 10 during a wafer transfer process.

FIG. 12 is a view showing a state of a gas supply and exhaust state produced by the gate valve and the transfer chamber shown in FIG. 10 during the wafer transfer process.

### DETAILED DESCRIPTION OF THE EMBODIMENTS

### First Embodiment

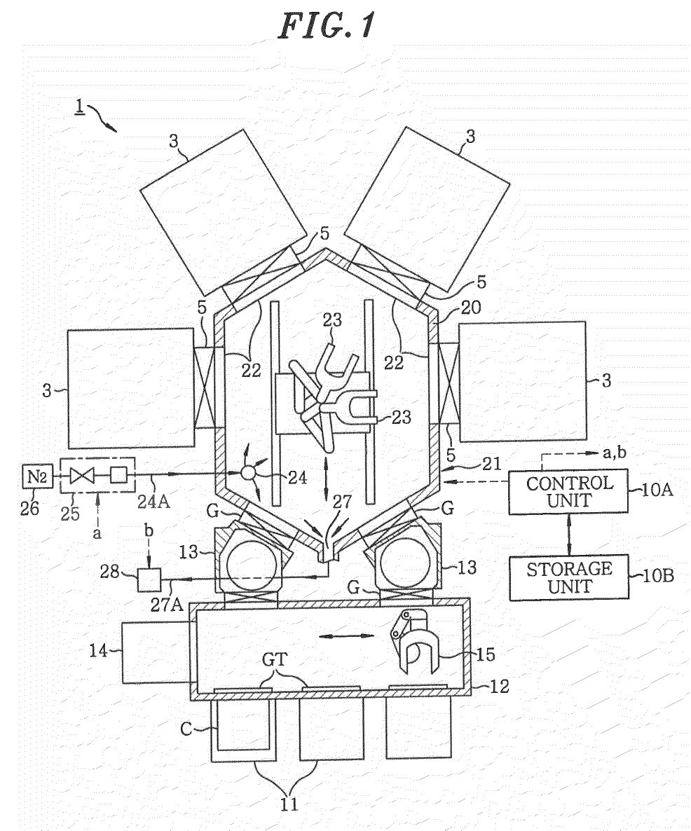

A configuration of a semiconductor manufacturing apparatus 1 to which a vacuum processing apparatus of the present invention is applied will be described with reference to FIG. 1. The semiconductor manufacturing apparatus 1 is a vacuum processing apparatus, which includes a first transfer chamber 12 constituting a loader module for loading and unloading a wafer W serving as a substrate, load lock chambers 13, a second transfer chamber 21, and a plurality of CVD modules 3, each having a processing chamber 30 connected with the second transfer chamber 21 via a gate chamber 5. A multiplicity of, e.g., 25, wafers W are accommodated in a sealable carrier C and transferred to the semiconductor manufacturing apparatus 1. Load ports 11 on which carriers C are mounted are disposed in front of the first transfer chamber 12. Provided on the front wall of the first transfer chamber 12 are gate doors GT that are connected with the carriers C mounted on the load ports 11. Each gate door GT is opened and closed together with a cover of the carrier C.

Further, an alignment chamber 14 is provided on a side of the first transfer chamber 12. A vacuum pump and a leak valve (all not shown) are provides for a load lock chambers 13, which are configured to switch the insides thereof between the atmospheric pressure and a vacuum state. That is, since the first and the second transfer chamber 12 and 21 are maintained at the atmospheric pressure and the vacuum state, respectively, the load lock chambers 13 serve to adjust the atmosphere during the transfer process of the wafer W between the transfer chambers 12 and 21. Gate chambers G having gate valves, i.e., sluice valves, that can be opened and closed are provided between the load lock chambers 13 and the first transfer chamber 12 and between the load lock chambers 13 and the second transfer chamber 21. These chambers are isolated from each other by closing the gate valves except when the wafer W is transferred.

The first transfer chamber 12 has a first transfer unit 15, which transfers the wafer W among the carrier C, the load lock chambers 13, and the alignment chamber 14.

The second transfer chamber 21 has a housing 20 formed in, e.g., a hexagonal shape, and four wafer transfer ports 22 are opened on the sidewalls thereof. The transfer ports 22 are connected with the CVD modules 3 serving as processing modules via the gate chambers 5 to be described later. Further, the second transfer chamber 21 has second transfer units 23 formed of multi-joint transfer arms for transferring the wafer W between the load lock chambers 13 and the CVD modules 3.

A gas supply port 24 serving as a gas supply unit is provided on the bottom surface of the housing 20 of the second transfer chamber 21. A gas supply line 24A has one end connected with the gas supply port 24 and the other end connected with a gas supply source 26 storing therein a non-reactive gas, e.g., N₂ gas, via a gas supply control mechanism 25 including a valve and a mass flow controller. Moreover, a gas exhaust port 27 is disposed on the sidewall of the housing 20. A gas exhaust line 27A has one end connected with the gas exhaust port 27 and the other end connected with a gas exhaust unit 28, which includes a vacuum pump or the like and having a pressure adjustment unit (not shown).

The gas supply control mechanism 25 receives a control signal from a control unit 10A to be described later, and controls the supply of N₂ gas to the second transfer chamber 21. The gas exhaust unit 28 receives a control signal from the control unit 10A and adjusts the pumping rate, such that a stream for exhausting particles is produced in the second transfer chamber 21 and the inside of the second transfer chamber 21 is controlled to a certain pressure level.

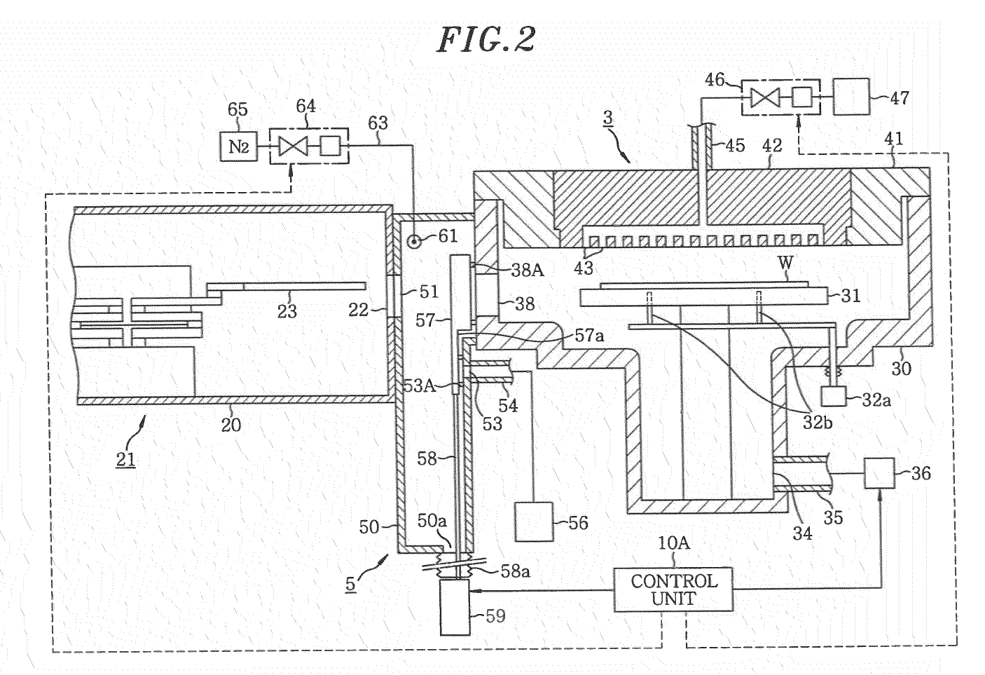

FIG. 2 is a vertical side view of the second transfer chamber 21, the gate chamber 5 and a CVD module 3. The CVD module 3 has the processing chamber 30, and a stage 31 for horizontally mounting thereon the wafer W is provided in the processing chamber 30. The stage 31 is provided with a heater (not shown) and three elevating pins 32b (only two are shown for convenience) capable of vertically moving by an elevation mechanism 32a. The wafer W is transferred between a second transfer unit 23 of the second transfer chamber 21 and the stage 31 via the elevating pins 32b.

A gas exhaust port 34 is provided at the lower portion of the processing chamber 30, and is connected to a gas exhaust unit 36, which includes a vacuum pump or the like via a gas exhaust line 35. The gas exhaust unit 36 receives a control signal from the control unit 10A, and exhausts the processing chamber 30 at a preset pumping rate so that a certain vacuum level is maintained therein. Further, the processing chamber 30 has on its sidewall facing the gate chamber 5 a transfer port 38 for the wafer W, which is disposed at a position corresponding to the transfer port 22 of the second transfer chamber 21. Further, an O-ring 38A, i.e., a ring-shaped resin seal member is provided on an outer wall of the processing chamber 30 to surround the transfer port 38.

A gas shower head 42 having a plurality of gas supply openings 43 is provided at a ceiling portion of the processing chamber 30 via a supporting member 41 to face the stage 31. The gas supply openings 43 are connected to a gas supply source 47 storing therein a processing gas such as a film forming gas for forming a film on the wafer W, e.g., TiCl₄, WF₆ or the like, via a gas supply line 45 connected with the gas shower head 42. Moreover, a gas supply control unit 46 including a valve and a mass flow controller installed on the gas supply line 45 receives a control signal from the control unit 10A and controls the supply of the processing gas into the processing chamber 30.

Besides, in the respective CVD modules 3 connected with the second transfer chamber 21, different films may be formed on the wafer W by making the difference in, e.g., the processing temperature of the wafer W, the processing pressure, the film forming gas and the like.

Next, the gate chamber 5 will be described. The gate chamber 5 is formed by a longitudinally elongated housing 50 and a wall portion of the processing chamber 30. The housing 50 has on its one sidewall facing the second transfer chamber 21 a transfer port 51 to overlap with the transfer port 22. Further, on its opposite sidewall facing the CVD module 3, e.g., a horizontally elongated slit-shaped gas exhaust port (gate chamber exhaust port) 53 is formed below the transfer port 38 of the CVD module 3. A gas exhaust line 54 has one end connected with the gas exhaust port 53 and the other end connected with a gas exhaust unit 56 including, e.g., a vacuum pump or the like having a pressure adjustment unit. In addition, an O-ring 53A, i.e., a ring-shaped resin seal member is provided at the housing 50 to surround the gas exhaust port 53.

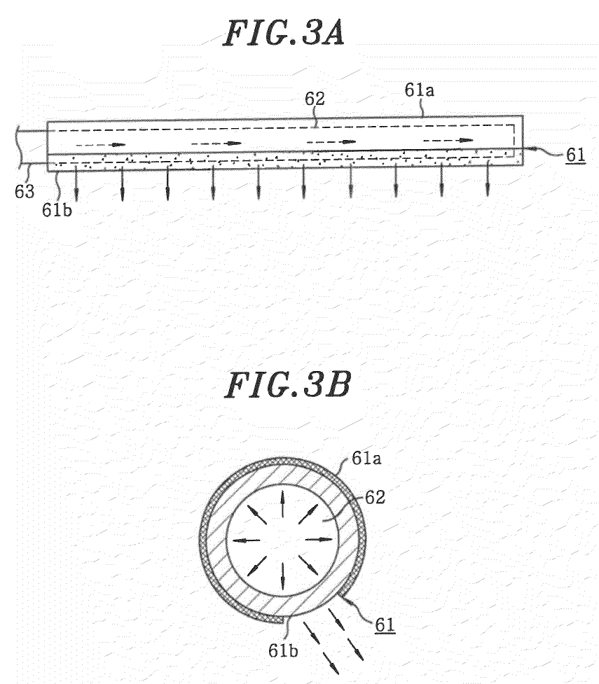

A gas nozzle 61 serving as a gate chamber non-reactive gas supply unit is provided at an upper portion of the inside of the housing 50. Referring to FIGS. 3A and 3B, the gas nozzle 61 is formed of a horizontally elongated cylindrical body having a closed one end, and a gas path 62 is formed therein. The side circumferential wall of the gas nozzle 61 is formed of a so-called break filter made of a sintered material, e.g., ceramic or the like, having a porous structure. A number of pores are formed in the side circumferential wall of the gas nozzle 61. A gas passageway having a three-dimensional net shape is formed by the pores communicating with one another. Further, a cover 61a is provided on the surface of the side circumferential wall, and a slit 61b is formed at the cover 61a along the length direction of the gas nozzle 61. The gas supplied to the path 62 is supplied through the slit 61b to a region in front of the transfer port 38 in a slantingly downward direction, and the flow velocities of the gas supplied from varying locations in the slit 61b are almost uniform.

A gas supply line 63 has one end connected with the path 62 and the other end connected with a gas supply source 65 storing therein N₂ gas via a gas supply control unit 64 including a valve and a mass flow controller. The gas supply control unit 64 receives a control signal from the control unit 10A, and controls the supply of N₂ gas from the gas supply source 65 to the gas nozzle 61.

As illustrated in FIG. 2, the housing 50 has therein the gate valve 57. The gate valve 57 has a step portion 57a on its backside (a side facing the CVD module 3), and a lower side of the step portion 57a serves as an opening/closing valve for the gas exhaust port 53. A supporting portion 58 is provided below the gate valve 57, and extends to the outside of the housing 50 via an opening 50a formed at the lower portion of the housing 50 to be connected with a driving unit 59. An extensible and contractible bellows 58a is disposed along the circumferential direction of the corresponding opening 50a at the outer side of the portion where the supporting portion 58 passes through the opening 50a so that the inside of the housing 50 can be air-tightly maintained. The driving unit 59 receives a control signal from the control unit 10A, and horizontally and vertically moves the gate valve 57 with respect to the transfer port 38 via the supporting portion 58 to thereby open and close the transfer port 38 and the gas exhaust port 53.

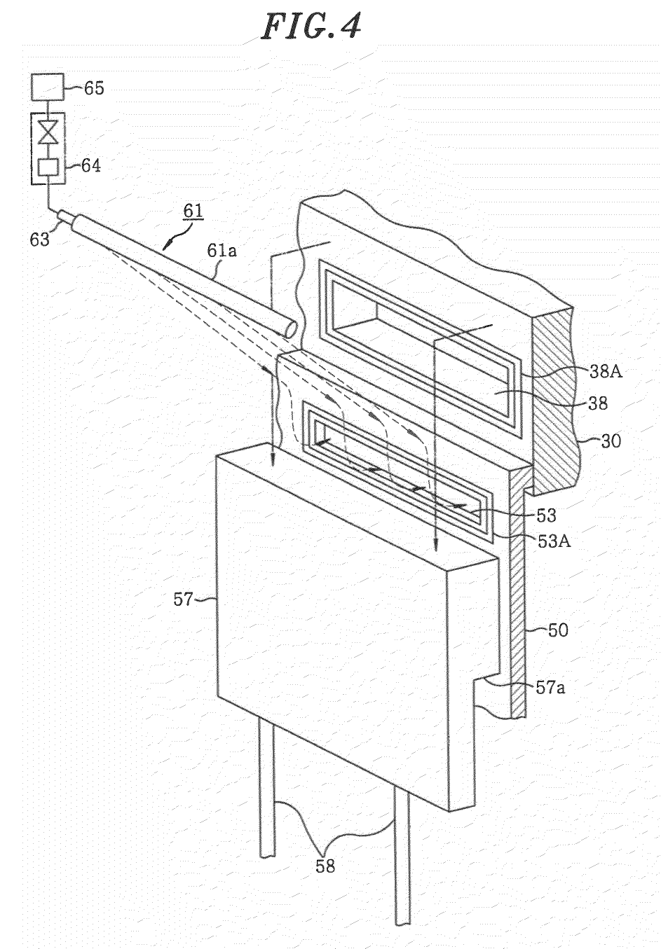

FIG. 4 shows a state where the gate valve 57 is lowered and the transfer port 38 and the gas exhaust port 53 are opened. As will be described later, N₂ gas is supplied from the gas nozzle 61 and is exhausted from the gas exhaust port 53 when the gate valve 57 is opened. Accordingly, a stream of N₂ gas is produced in a region facing the transfer port 38, and thus the gas introduced from the processing chamber 30 into the housing 50 is prevented from being diffused into the housing 50 to flow toward the second transfer chamber 21.

The supply rate of N₂ gas from the gas nozzle 61 of the gate chamber 5 and the pumping rate through the gas exhaust port 53 are separately controlled in accordance with the processing pressure of the wafer W in the connected CVD module 3, such that the gas remaining in the processing chamber 30 can flow toward the gas exhaust port 53 by the formed N₂ gas stream, without being diffused into the second transfer chamber 21.

Further, when the transfer port 38 and the gas exhaust port 53 are closed by raising the gate valve 57, a portion positioned upper than the step portion 57a of the backside of the gate valve 57 becomes adhered to the outer wall of the processing chamber 30 via the O-ring 38A by the driving unit 59 and, also, a portion positioned lower than the step portion 57a becomes adhered to the housing 50 via the O-ring 53A. Accordingly, the housing 50 and the processing chamber 30 of the CVD module 3 are air-tightly isolated from each other, and the inside of the gas exhaust port 53 is also hermetically sealed.

The semiconductor manufacturing apparatus 1 includes a control unit 10A constituted by, e.g., a computer. The control unit 10A has a data processing unit formed of a program, a memory, a CPU and the like. The program serves to send control signals from the control unit 10A to various units of the semiconductor manufacturing apparatus 1 and includes instructions (steps) for performing a process of transfer and processing of the wafer W which includes operations of opening and closing of the gate valve 57 of the gate chamber 5, as will be described later. Further, the memory has, e.g., an area in which processing parameter values of each processing module, such as a processing pressure, a processing temperature, processing time, a gas flow rate, a power level and the like, are written. When the CPU executes the instruction of the program, these processing parameter values are read out and the control signals in accordance with the parameter values are sent to corresponding units of the semiconductor manufacturing apparatus 1. The program (including a program for inputting and/or displaying of processing parameters) is stored in a storage unit 10B such as a computer storage medium, e.g., a flexible disk, a compact disk, a hard disk, an MO (magneto-optical) disk or the like, and is installed in the control unit 10A.

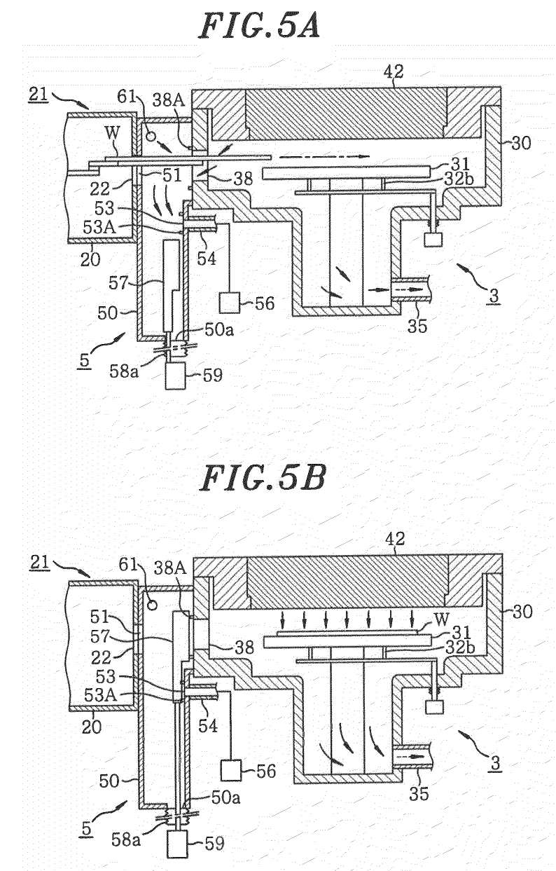

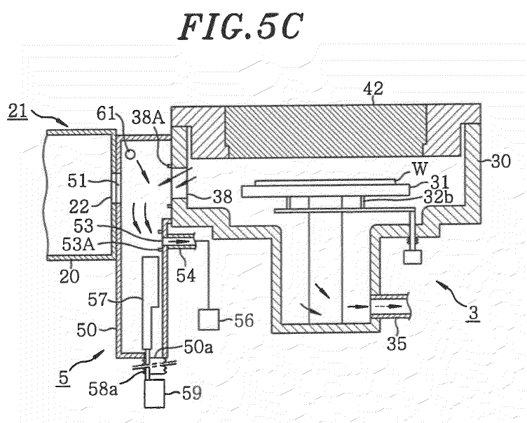

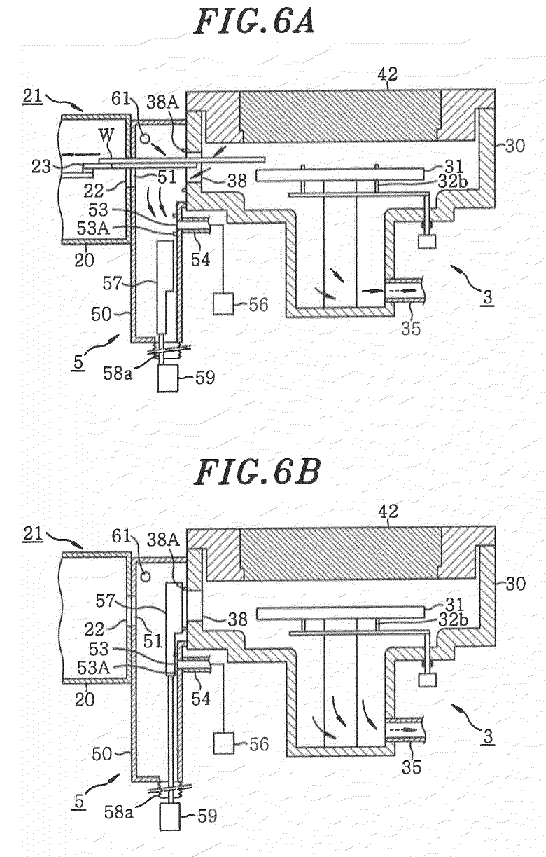

Hereinafter, an operation of the semiconductor manufacturing apparatus 1 will be explained with reference to FIGS. 5A to 6B. First of all, a carrier C is transferred to the semiconductor manufacturing apparatus 1 and mounted on a load port 11 to be connected with the first transfer chamber 12. At this time, in the housing 20 of the second transfer chamber 21 of the semiconductor manufacturing apparatus 1, N₂ gas is supplied from the gas supply port 24 and is exhausted from the gas exhaust port 27, so that the pressure therein is maintained at several tens to several hundreds of Pa. Further, in the processing chamber 30 of each CVD module 3, the gas is exhausted through the gas exhaust port 34, so that the pressure in the processing chamber 30 is maintained at a level lower than several tens to several hundreds of Pa.

When the carrier C is connected to the first transfer chamber 12, the gate door GT and the cover of the carrier C are opened at the same time and a wafer W in the carrier C is loaded into the first transfer chamber 12 by the first transfer unit 15. Next, the wafer W is transferred to the alignment chamber 14 for adjusting a direction or eccentricity of the wafer W, and then is transferred to the load lock chamber 13. After the pressure in the load lock chamber 13 is controlled, the wafer W is loaded by the second transfer unit 23 from the load lock chamber 13 into the second transfer chamber 21 maintained at a vacuum atmosphere.

Thereafter, N₂ gas is supplied from the gas nozzle 61 in the gate chamber 5 connected with a predetermined CVD module 3. Next, the gate valve 57 is separated from the O-rings 38A and 53A by the driving unit 59 and then slides downward so that the transfer port 38 and the gas exhaust port 53 are opened. At this time, the gas in the housing 50 is exhausted through the gas exhaust port 53, so that an N₂ gas stream is formed from the gas nozzle 61 toward the gas exhaust port 53 within the gate chamber 5. Therefore, if the gas remaining in the processing chamber 30 is introduced into the housing 50 of the gate chamber 5 through the transfer port 38, such gases is made to flow toward the N₂ gas stream and are exhausted through the gas exhaust port 53 together with the N₂ gas stream.

While the N₂ gas stream is formed within the gate chamber 5, a wafer (not shown) processed in the CVD module 3 is extracted from the processing chamber 30 by the second transfer unit 23 which does not hold a wafer W and the second transfer unit 23 which holds the wafer W to be processed enters into the processing chamber 30 through the transfer port 38 (FIG. 5A).

When the elevating pins 32b are raised and receive the wafer W in the processing chamber 30, the second transfer unit 23 retreats from the processing chamber 30 and the elevating pins 32b are lowered so that the wafer W is mounted on the stage 31 and is maintained at a predetermined temperature by a heater in the stage 31. Further, the gate valve 57 is raised so that the backside thereof becomes adhered to the O-rings 38A and 53A, and the transfer port 38 and the gas exhaust port 53 are closed. When the processing chamber 30 is maintained at a predetermined pressure by vacuum-exhaust, a film forming gas, e.g., TiCl₄ gas or the like, is supplied from the gas shower head 42, thereby forming a film on the wafer W (FIG. 5B).

Upon completion of the film forming process, the supply of the film forming gas from the gas shower head 42 is stopped. When the inside of the processing chamber 30 is maintained at a predetermined pressure, N₂ gas is supplied from the gas nozzle 61. Then, the gate valve 57 of the gate chamber 5 is lowered by the driving unit 59. Accordingly, the transfer port 38 and the gas exhaust port 53 are opened, and the gas in the housing 50 is exhausted through the gas exhaust port 53. As a consequence, the N₂ gas stream flowing from the gas nozzle 61 toward the gas exhaust port 53 is formed in front of the transfer port 38 (FIG. 5C).

Therefore, if the film forming gas remaining in the processing chamber 30 of the CVD module 3 or the by-production gas is introduced into the housing 50 of the gate chamber 5 through the transfer port 38, such gas is made to flow toward the N₂ gas stream, as indicated by arrows in the drawing, and then are exhausted through the gas exhaust port 53 together with the N₂ gas stream.

When the N₂ gas stream is formed in the housing 50 of the gate chamber 5, the second transfer unit 23 is entered into the processing chamber 30, and the wafer W is transferred from the stage 31 to the second transfer unit 23 via the elevating pins 32b. The second transfer unit 23 transfers the wafer W to the second transfer chamber 21 via the transfer ports 38, 51 and 22 (FIG. 6A). Thereafter, the gate valve 57 is raised so that the backside thereof becomes adhered to the O-rings 38A and 53A. Consequently, the gas exhaust port 53 and the transfer port 38 are closed and thus the exhaust through the gas exhaust port 53 is stopped. Then, substantially at the same time, the supply of the gas from the gas nozzle 61 is stopped (FIG. 6B).

Next, the wafer W is transferred as the above, e.g., to each of other CVD modules 3 and subjected to a predetermined film forming process therein in a manner described above. Upon completion of all required film forming processes, the wafer W is transferred to the first transfer unit 15 via the load lock chamber 13 by the second transfer unit 23 and then returned to the carrier C by the first transfer unit 15.

In accordance with the above embodiment, the gate chamber 5 is provided with the gate valve 57 for opening and closing the transfer port 38 of the processing chamber 30 and the gas exhaust port 53 of the gate chamber 5. The gate chamber 5 is further provided with the gas nozzle 61, such that a gas stream is formed in front of the transfer port 38 by the gas nozzle 61 and the gas exhaust port 53. After the wafer W is processed in the processing chamber 30, the transfer port 38 and the gas exhaust port 53 are opened by opening the gate valve 57, while N₂ gas is supplied from the gas nozzle 61 and exhausted from the gas exhaust port 53, such that a gas stream for removing a gas remaining in the processing chamber 30 and then being introduced from the transfer port 38 and is formed at a region facing the transfer port 38.

Accordingly, it is possible to suppress the contamination of the second transfer chamber 21 due to the remaining gas diffusing into the second transfer chamber 21. This can suppress the contamination of the wafer W or the occurrence of cross contamination of the wafer W by particles generated from the remaining gas. Further, when a corrosive gas is used as a processing gas of the CVD module, it is possible to prevent various parts of the second transfer chamber 21 from being damaged by the diffusion of the corrosive gas.

Besides, when the wafer W is transferred into or out of the CVD module 3, the non-reactive gas flows only in the gate chamber 5 connected with the CVD module 3. Therefore, N₂ gas can be less consumed compared to the case of maintaining a large pressure difference between the second transfer chamber 21 and the CVD module 3 by increasing the supply rate of N₂ gas to the second transfer chamber 21, which leads to the cost reduction. Further, in this embodiment, since the transfer port 38 and the gas exhaust port 53 are opened and closed simultaneously by the gate valve 57, the gas exhaust port 53 is surely opened when the transfer port 38 is opened. Accordingly, the gas diffused from the gas transfer port 38 can be exhausted from the gas exhaust port 53.

In the above embodiment, there is shown an example in which, after the film forming process on the wafer W is completed, the supply and the exhaust of N₂ gas is carried out in the gate chamber 5 to thereby prevent the gas diffusion from the processing chamber 30 to the second transfer chamber 21. For example, however, a gas may be supplied from the gas shower head 42 before initiating the film forming process, in order to produce a processing atmosphere in the processing chamber 30. In that case, it is also necessary to supply and exhaust the N₂ gas when the transfer port 38 is opened after supplying the gas in the processing chamber 30, enabling to prevent the gas used to produce the processing atmosphere from diffusing into the second transfer chamber 21. Further, in the above embodiment, closing the gate valve 57 and stopping the gas supply from the gas nozzle 61 may not be conducted simultaneously, but these timings may be slightly differed.

Moreover, the technical scope of the present invention also includes the case where a stream of N₂ gas is produced by continuously performing the gas supply from the gas nozzle 61 and the gas exhaust through the gas exhaust port 53 in the gate chamber 5 without closing the gas exhaust port 53 even when the transfer port 38 is closed by the gate valve. However, in order to prevent disturbance of the stream in the second transfer chamber 21, it is preferable to form the stream of N₂ gas only when the gate valve 57 is opened as described above. Further, the present invention is not limited to the case where the multi-chamber type vacuum processing apparatus includes a plurality of processing chambers as in the semiconductor manufacturing apparatus 1, but may be applied to a case where a single processing chamber is connected with a load lock chamber having a transfer unit. In that case, the load lock chamber corresponds to the transfer chamber described in the claims.

In addition, in the above embodiment, if the N₂ gas stream produced by the gas nozzle 61 and the gas exhaust port 53 is affected by the shape of the second transfer chamber 21 or the position of the transfer port 38, the gas exhaust port 27 may be closed or a gas exhaust line connected with the gas exhaust port 27 may be closed.

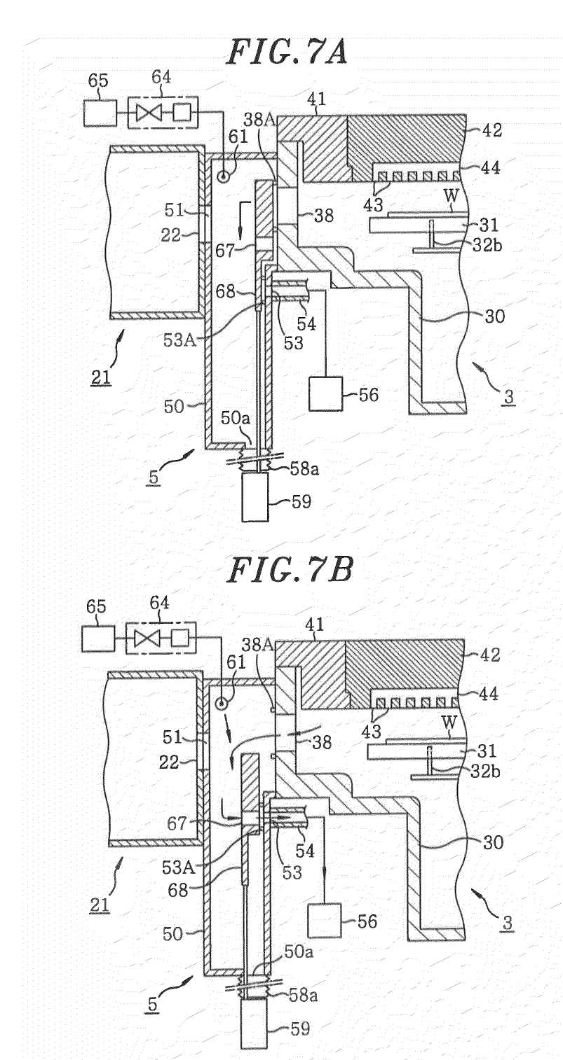

FIG. 7A shows a modification of the gate valve of the first embodiment. In this modification, a gate valve 68 differing from the gate valve 57 is employed. The gate valve 68 is different from the gate valve 57 in that an opening 67 provided to communicate with the gas exhaust port 53 is formed in a thickness direction of the gate valve 68. When the gate valve 68 is closed, the opening 67 is positioned at a height between the lower end of the O-ring 38A and the upper end of the O-ring 53A so as not to disturb the sealing of the transfer port 38 of the processing chamber 30 and the gas exhaust port 53 by the gate valve 68. Further, as can be seen from FIG. 7B, when the wafer W is transferred, the opening 67 slides downward so as to overlap with the gas exhaust port 53, thereby opening the gas exhaust port 53 and the transfer port 38.

With this configuration, the moving stroke of the gate valve 68 can be reduced, and the elevation mechanism can be simplified. This can shorten a period of time required from when the transfer port 38 is opened to when the gas exhaust port 53 is opened, so that the gas introduction from the processing chamber 30 to the second transfer chamber 21 can be suppressed more effectively.

### Second Embodiment

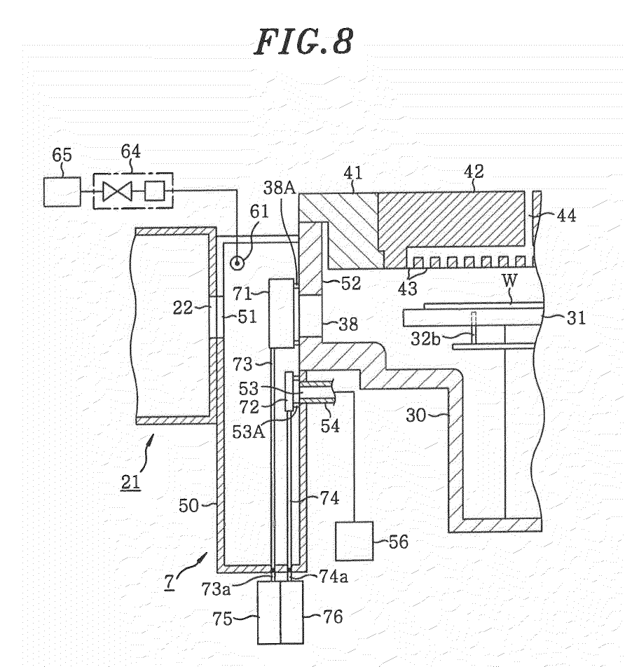

Hereinafter, another embodiment of the semiconductor manufacturing apparatus will be described with reference to FIG. 8. This semiconductor manufacturing apparatus is configured identical to the semiconductor manufacturing apparatus 1 except that a gate chamber 7 is provided instead of the gate chamber 5. The gate chamber 7 is different from the gate chamber 5 in that a gate valve 71 for opening and closing the transfer port 38 and a gate valve 72 for opening and closing the gas exhaust port 53 are separately provided.

The gate valves 71 and 72 are formed in a rectangular shape so as to correspond to the transfer port 38 and the gas exhaust port 53, respectively. The gate valves 71 and 72 are connected with the driving units 75 and 76 via the supporting portions 73 and 74 formed in a manner as in the supporting portion 58. Further, driving units 75 and 76 slide the gate valves 71 and 72 in a vertical direction, respectively, and allows the backsides of the gate valves 71 and 72 to be adhered to the outer wall of the processing chamber 30 and the wall portion of the housing 50 via the O-rings 38A and 53A, respectively.

Accordingly, the opening and closing of the transfer port 38 and the gas exhaust port 53 can be separately carried out. Moreover, the supporting portions 73 and 74 extend to the outside of the housing 50 via the openings 73a and 74a provided at the lower portion of the housing 50, respectively. Further, as in the gate chamber 5, a bellow is disposed around the circumference of each of the openings 73a and 74a to maintain the airtightness of the housing 50. However, the illustration of the bellows is omitted for simplicity.

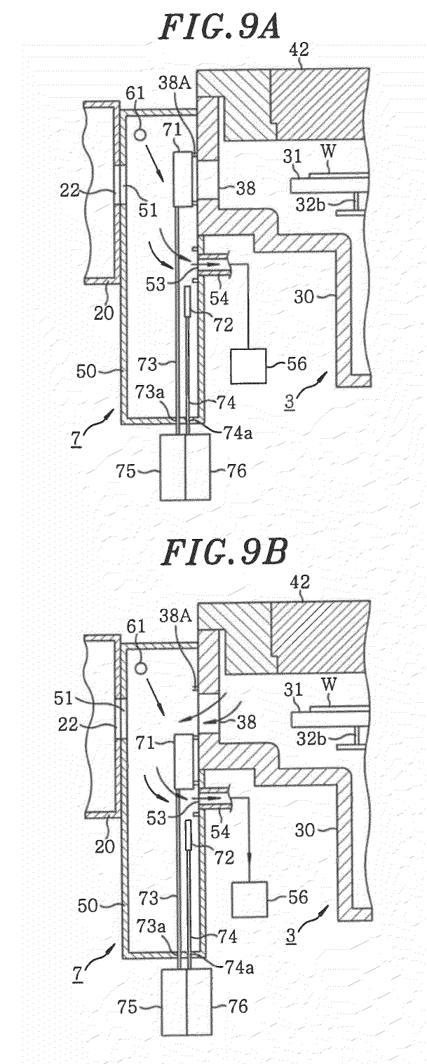

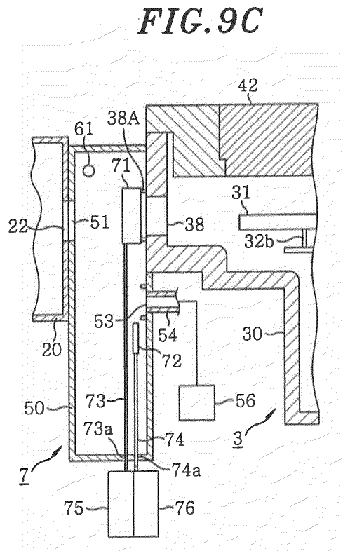

FIGS. 9A to 9C illustrates states where the wafer W that has been subjected to the film forming process is transferred from the CVD module 3 to the second transfer chamber 21 in the semiconductor manufacturing apparatus having the gate chamber 7. When the film forming process is completed in the CVD module 3, the gate valve 72 slides downward by the driving unit 76 from the position shown in FIG. 8. Accordingly, the gas exhaust port 53 is opened, and a gas in the housing 50 is exhausted from the gas exhaust port 53. Further, N₂ gas is supplied from the gas nozzle 61 into the housing 50 at the same time when or slightly after the gas starts to be exhausted through the gas exhaust port 53. Thereafter, as in the gate chamber 5, an N₂ gas stream flowing from the gas nozzle 61 toward the gas exhaust port 53 is formed at a region facing the transfer port 38 (FIG. 9A).

When the N₂ gas stream is formed in the gate chamber 7, the gate valve 71 slides downward, and the transfer port 38 is opened. At that time, even if the gas remaining in the processing chamber 30 is discharged to the housing 50 through the transfer port 38, the gas is removed through the gas exhaust port 53 together with N₂ gas (FIG. 9B). Further, after the wafer W is unloaded from the processing chamber 30, the gate valve 71 is raised and the transfer port 38 is closed (FIG. 9C); and slightly later, the supply of N₂ gas from the gas nozzle 61 is stopped and the gate valve 72 is closed, thereby stopping the gas exhaust from the gas exhaust port 53.

In accordance with the second embodiment, the opening and closing of the transfer port 38 and the gas exhaust port 53 can be independently conducted. Accordingly, the N₂ gas stream flowing from the gas nozzle 61 toward the gas exhaust port 53 can be formed at a region facing the transfer port 38 before the transfer port 38 is opened and, also, the formation of the N₂ gas stream can be continued even after the transfer port 38 is closed. As a consequence, it is possible to effectively suppress the introduction of the gas remaining in the processing chamber 30 into the second transfer chamber 21 through the transfer port 38.

In addition, instead of providing the gate valve 72 of the second embodiment, a valve may be installed in the gas exhaust line 54 connected with the gas exhaust port 53, for example. In that case, the gas exhaust from the gas exhaust port 53 can be controlled by opening and closing the valve. Such a case is also included in the claims of the present invention.

### Third Embodiment

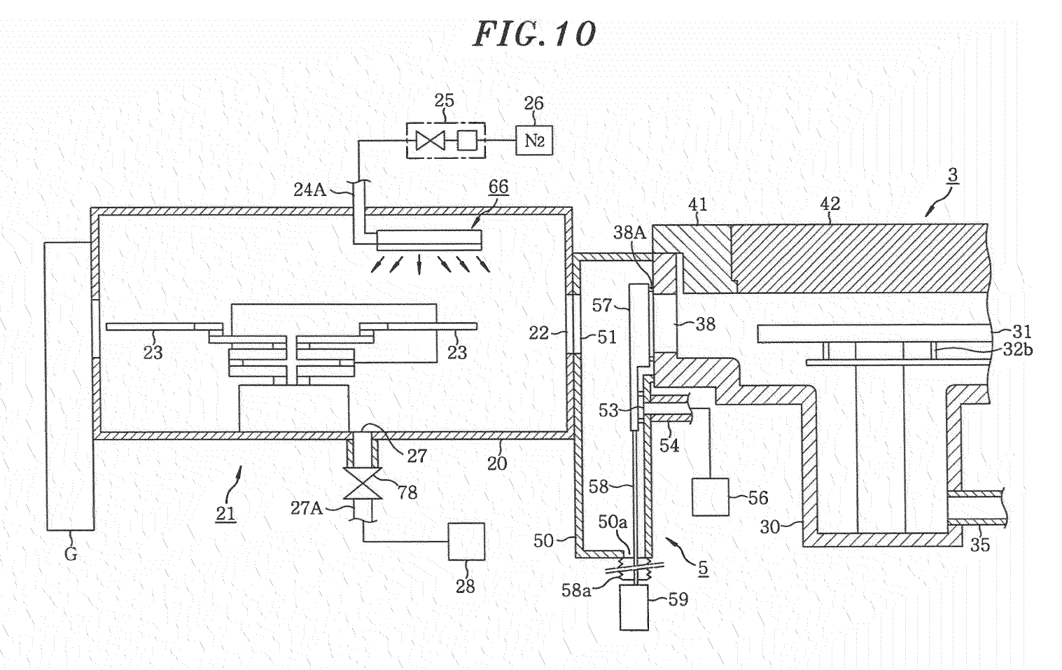

Hereinafter, another embodiment of the semiconductor manufacturing apparatus will be described with reference to FIG. 10. The semiconductor manufacturing apparatus of the third embodiment is different from the semiconductor manufacturing apparatus 1 of the first embodiment in that the gas nozzle 61 is not provided at the gate chamber 5, and also in that the gas supply line 24A is connected with a gas nozzle (transfer chamber non-reactive gas supply unit) 66 provided at the central portion of the ceiling portion of the second transfer chamber 21, instead of being connected with the bottom surface of the housing 20.

The gas nozzle 66 is configured in a manner as in the gas nozzle 61, and supplies N₂ gas downward. Furthermore, the gas exhaust port (transfer chamber exhaust port) 27 opens, instead of being disposed on the sidewall of the housing 20, e.g., at a position that does not disturb the passageway of the second transfer unit 23 near the center of the bottom surface of the second transfer chamber 21. A reference numeral 78 indicates a valve installed on a gas exhaust line 27A. As will be described later, the valve 78 is opened except when the transfer port 38 is opened, and the gas is exhausted from the gas exhaust port 27. Further, while the valve 78 is opened, N₂ gas is supplied from the gas nozzle 66, and the pressure in the second transfer chamber 21 is maintained at, e.g., several tens to several hundreds of Pa.

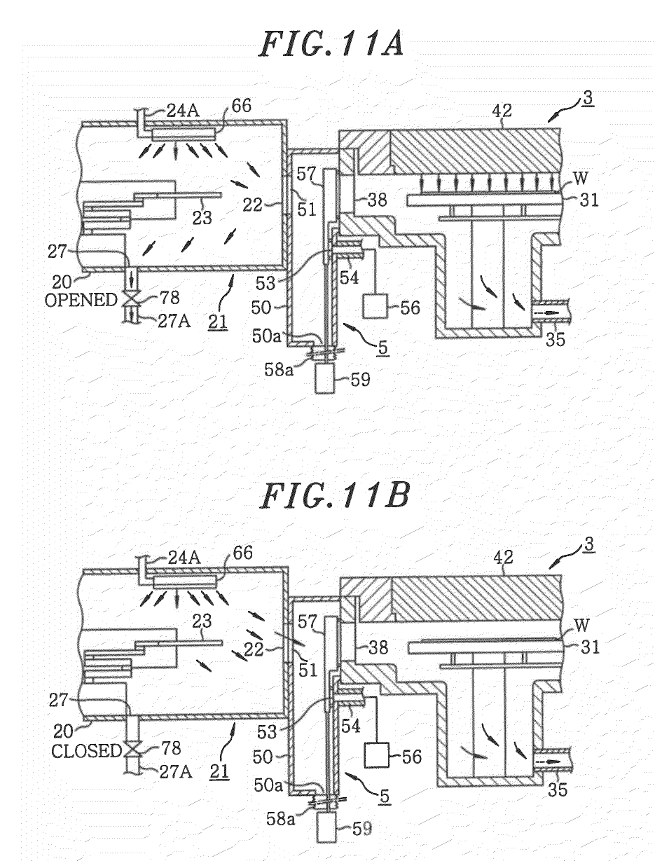

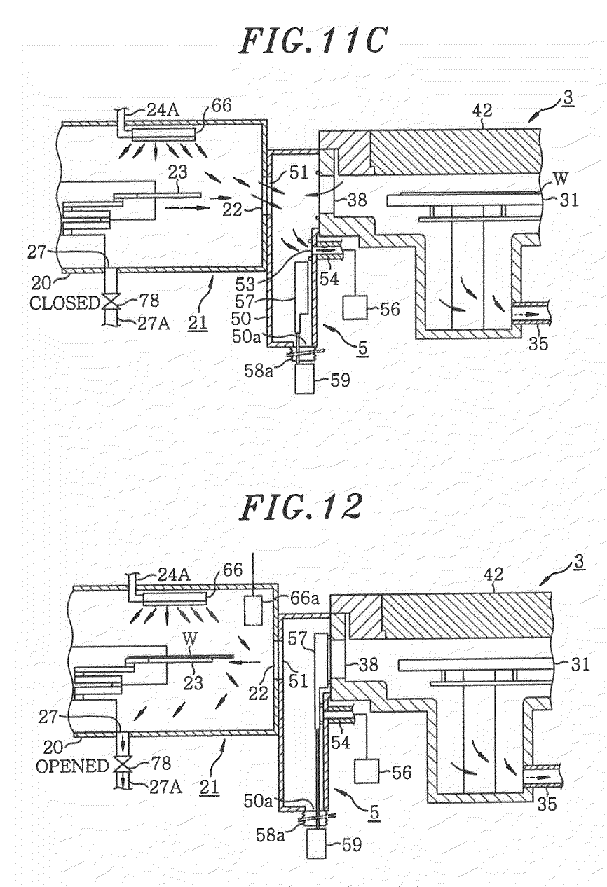

FIGS. 11A to 12 show states when the wafer W is transferred from the CVD module 3 in the semiconductor manufacturing apparatus of the third embodiment. Upon completion of the film forming process of the wafer W, the valve 78 is closed, and the gas exhaust from the gas exhaust port 27 is stopped (FIGS. 11A and 11B). Then, the gate valve 57 of the gate chamber 5 is lowered, and the gas is exhausted through the gas exhaust port (gate chamber exhaust port) 53.

Therefore, N₂ gas supplied from the gas nozzle 66 is introduced into the housing 50 via the transfer ports 22 and 51, and is exhausted from the gas exhaust port 53. Thus, an N₂ gas stream flowing from the gas nozzle 66 toward the gas exhaust port 53 is formed. Therefore, even if the gas remaining in the processing chamber 30 is discharged to the housing 50, the remaining gas is made to flow toward the N₂ gas flow and is exhausted from the gas exhaust port 53 (FIG. 11C).

After the wafer W is unloaded from the processing chamber 30 by the second transfer unit 23, the gate valve 57 is raised to close the transfer port 38 and the gas exhaust port 53, and thus the gas exhaust through the gas exhaust port 53 is stopped. Further, the valve 78 is opened substantially at the same time when or slightly after the gas exhaust port 53 is closed, and thus the gas is exhausted from the gas exhaust port 27 (FIG. 12).

With this configuration, the same effects as those in the first embodiment can be obtained. Moreover, in this embodiment, the valve 78 is closed and thus the gas exhaust from the gas exhaust port 27 is stopped, the N₂ gas stream flowing from the gas nozzle 66 toward the gas exhaust port 53 is formed effectively.

The gas nozzle 66 serves as a first transfer chamber non-reactive gas supply unit which prevents diffusion of a remaining gas and forms together with the gas exhaust port 53 of the gate chamber 5 a stream of a non-reactive gas at a region facing the transfer port 38; and also serves as a second transfer chamber non-reactive gas supply unit which forms a stream of a non-reactive gas in the transfer chamber 21 in cooperation with the gas exhaust port 27.

In the third embodiment, the gas supply nozzle 66 for forming a stream in the transfer chamber 21 is used as a gas supply port for the gate chamber 5. However, e.g., a dedicated gas nozzle 66a for forming an exhaustive gas stream in the gate chamber 5 may be provided in the second transfer chamber 21 near each gate chamber 5, in addition to the gas supply nozzle 66. In that case, the gas supply nozzle 66 serves only as the second transfer chamber non-reactive gas supply unit for forming a stream within the transfer chamber, and the gas exhaust from the gas exhaust port 27 of the second transfer chamber 21 may not be stopped.

Further, in the third embodiment, when the completion signal of the film forming process in the CVD module 3 is transmitted to the control unit 10A, the gate valve 57 is opened in the gate chamber 5 connected with the corresponding processing chamber 30, and the gas exhaust is carried out as described above. This completion signal may be generated by detecting the upward movement of the elevating pins 32b.

Moreover, various substrates other than the wafer, e.g., an LCD substrate, a glass substrate, a ceramic substrate or the like can be processed in the above-described embodiments. Furthermore, N₂ gas is used as an example of a non-reactive gas supplied from the gas nozzle and the gas supply port in the above-described embodiments. However, the non-reactive gas is not limited to N₂, and may be a rare gas such as He (helium), Ne (neon), Ar (argon) or the like, or another gas such as H₂ (hydrogen) or the like.

What is claimed is:

1. A vacuum processing apparatus comprising:
a processing chamber having a substrate transfer port and performing a processing on a substrate by using a processing gas in a vacuum atmosphere;
a transfer chamber in a vacuum atmosphere connected via a gate chamber to the transfer port of the processing chamber and equipped with a transfer unit for transferring the substrate with respect to the processing chamber;
a gate valve provided in the gate chamber for closing the transfer port when the substrate is processed in the processing chamber and opening the transfer port when the substrate is transferred with respect to the processing chamber; and
a gate chamber non-reactive gas supply unit and a gate chamber exhaust port provided at the gate chamber, which produce a stream of a non-reactive gas at a region facing the transfer port to suppress diffusion of a gas remaining in the processing chamber into the transfer chamber at least while the transfer port is opened.

2. The vacuum processing apparatus of claim 1, wherein when the gate valve in the gate chamber is closed, the supply of the non-reactive gas from the gate chamber non-reactive gas supply unit is stopped.

3. The vacuum processing apparatus of claim 1, wherein the transfer chamber is provided with a transfer chamber non-reactive gas supply unit and a transfer chamber exhaust port to produce a stream of non-reactive gas within the transfer chamber.

4. The vacuum processing apparatus of claim 2, wherein the transfer chamber is provided with a transfer chamber non-reactive gas supply unit and a transfer chamber exhaust port to produce a stream of non-reactive gas within the transfer chamber.

5. The vacuum processing apparatus of claim 1, wherein when the gate valve in the gate chamber is closed, the gate chamber exhaust port of the gate chamber is closed.

6. The vacuum processing apparatus of claim 1, wherein the gate valve is configured to open and close the gate chamber exhaust port in unison with the opening and closing of the transfer port.

7. The vacuum processing apparatus of claim 1, wherein the gate valve has an opening at a position overlapping with the gate chamber exhaust port such that the gate chamber exhaust port is opened while the transfer port is opened.

8. The vacuum processing apparatus of claim 1, further comprising one or more processing chambers, each being connected to the transfer chamber via a gate chamber.

9. A vacuum processing apparatus comprising:
a plurality of processing chambers, each having a substrate transfer port and performing a processing on a substrate by using a processing gas in a vacuum atmosphere;
a transfer chamber in a vacuum atmosphere connected via a gate chamber to the transfer port of the processing chambers and equipped with a transfer unit for transferring the substrate with respect to the processing chambers via the transfer port;
a gate valve provided in the gate chamber for closing the transfer port when the substrate is processed in the processing chamber and opening the transfer port when the substrate is transferred with respect to the processing chamber;
one or more first transfer chamber non-reactive gas supply units provided in the transfer chamber and a gate chamber exhaust port provided at the gate chamber, which produce a stream of a non-reactive gas at a region facing the transfer port to suppress diffusion of a gas remaining in said each of the processing chambers into the transfer chamber;
a second transfer chamber non-reactive gas supply unit provided in the transfer chamber to produce a stream of a non-reactive gas in the transfer chamber; and
a transfer chamber exhaust port provided in the transfer chamber to exhaust the transfer chamber and adapted to be closed when the stream of the non-reactive gas is produced in the gate chamber,
wherein, when the gate valve is closed, the gate chamber exhaust port of the gate chamber is closed.

10. The vacuum processing apparatus of claim 9, wherein the first transfer chamber non-reactive gas supply units are provided for the transfer ports of the processing chambers in a one-to-one relationship.

11. The vacuum processing apparatus of claim 9, wherein the number of the first transfer chamber non-reactive gas supply unit is one and a single unit is commonly used as the first and the second transfer chamber non-reactive gas supply unit.

12. An operating method of a vacuum processing apparatus which includes a processing chamber having a substrate transfer port, a transfer chamber connected via a gate chamber to the transfer port and equipped with a transfer unit for transferring a substrate with respect to the processing chamber via the transfer port in a vacuum atmosphere, the operating method comprising:
processing the substrate in the processing chamber with the use of a processing gas in a vacuum atmosphere while closing the transfer port by a gate valve provided in the gate chamber;
unloading the substrate from the processing chamber by the transfer unit while opening the transfer port by the gate valve; and
producing, at least while the transfer port is opened, a stream of a non-reactive gas at a region facing the transfer port by a gate chamber non-reactive gas supply unit and a gate chamber exhaust port provided at the gate chamber to suppress diffusion of a gas remaining in the processing chamber into the transfer chamber.

13. The operating method of claim 12, wherein when the gate valve of the gate chamber is closed, supply of the non-reactive gas from the gate chamber non-reactive gas supply unit is stopped.

14. The operating method of claim 12, further comprising producing a stream of a non-reactive gas in the transfer chamber by a transfer chamber non-reactive gas supply unit and a transfer chamber exhaust port provided at the transfer chamber.

15. The operating method of claims 12, wherein when the gate valve in the gate chamber is closed, the gate chamber exhaust port of the gate chamber is closed.

16. An operating method of a vacuum processing apparatus which includes a processing chamber having a substrate transfer port, a transfer chamber connected via a gate chamber to the transfer port and equipped with a transfer unit for transferring a substrate with respect to the processing chamber in a vacuum atmosphere, the operating method comprising:
processing the substrate in the processing chamber with the use of a processing gas in a vacuum atmosphere while closing the transfer port by a gate valve provided in the gate chamber;
unloading the substrate from the processing chamber by the transfer unit while opening the transfer port by the gate valve;
at least while the transfer port is opened, producing a stream of a non-reactive gas at a region facing the transfer port by a first transfer chamber non-reactive gas supply unit provided in the transfer chamber and a gate chamber exhaust port provided at the gate chamber, to suppress diffusion of a gas remaining in the processing chamber into the transfer chamber; producing a stream of a non-reactive gas in the transfer chamber by a second transfer chamber non-reactive gas supply unit provided in the transfer chamber; and closing an exhaust port provided at the transfer chamber to exhaust the transfer chamber when the stream of the non-reactive gas is produced in the gate chamber; and
closing the gate chamber exhaust port provided at the gate chamber when the gate valve is closed.

17. A storage medium storing therein a computer program for executing an operating method of a vacuum processing apparatus by computer which includes a processing chamber having a substrate transfer port, a transfer chamber connected via a gate chamber to the transfer port and equipped with a transfer unit for transferring a substrate with respect to the processing chamber via the transfer port in a vacuum atmosphere, wherein the operating method includes:
processing the substrate in the processing chamber with the use of a processing gas in a vacuum atmosphere while closing the transfer port by a gate valve provided in the gate chamber;
unloading the substrate from the processing chamber by the transfer unit while opening the transfer port by the gate valve; and
producing, at least while the transfer port is opened, a stream of a non-reactive gas at a region facing the transfer port by a gate chamber non-reactive gas supply unit and a gate chamber exhaust port provided at the gate chamber to suppress diffusion of a gas remaining in the processing chamber into the transfer chamber.

18. A storage medium storing therein a computer program for executing an operating method of a vacuum processing apparatus by computer which includes a processing chamber having a substrate transfer port, a transfer chamber connected via a gate chamber to the transfer port and equipped with a transfer unit for transferring a substrate with respect to the processing chamber in a vacuum atmosphere, the operating method comprising:
processing the substrate in the processing chamber with the use of a processing gas in a vacuum atmosphere while closing the transfer port by a gate valve provided in the gate chamber;
unloading the substrate from the processing chamber by the transfer unit while opening the transfer port by the gate valve;
at least while the transfer port is opened, producing a stream of a non-reactive gas at a region facing the transfer port by a first transfer chamber non-reactive gas supply unit provided in the transfer chamber and a gate chamber exhaust port provided at the gate chamber, to suppress diffusion of a gas remaining in the processing chamber into the transfer chamber; producing a stream of a non-reactive gas in the transfer chamber by a second transfer chamber non-reactive gas supply unit provided in the transfer chamber; and closing an exhaust port provided at the transfer chamber to exhaust the transfer chamber when the stream of the non-reactive gas is produced in the gate chamber; and
closing the gate chamber exhaust port provided at the gate chamber when the gate valve is closed.
